(19) United States
(12) Patent Application Publication
(10) Pub. No.: US 2023/0403820 A1
(43) Pub. Date: Dec. 14, 2023

(54) LIQUID-COOLED HEAT EXCHANGE SYSTEM AND CONTROL METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Ji LIAN, Zhangjiakou City (CN); Tao LU, Zhangjiakou City (CN)

(21) Appl. No.: 18/207,158

(22) Filed: Jun. 8, 2023

(30) Foreign Application Priority Data
Jun. 10, 2022 (CN) 202210656586.1

(51) Int. Cl. H05K 7/20

(52) U.S. Cl. CPC H05K 7/20281; H05K 7/20272

(57) ABSTRACT

The present disclosure discloses a liquid-cooled heat exchange system. An internal circulation loop at least includes an internal liquid inlet pipeline, an internal liquid return pipeline and a region to be heat-dissipated, a liquid outlet of an internal channel is communicated with a liquid inlet of the region to be heat-dissipated through the internal liquid inlet pipeline, and a liquid outlet of the region to be heat-dissipated is communicated with a liquid inlet of the internal channel through the internal liquid return pipeline. An electrically-controlled regulating valve is arranged at a liquid inlet of an external channel. A pump body is connected in series to the internal liquid inlet pipeline or the internal liquid return pipeline, a first temperature sensor is arranged at the liquid outlet of the region to be heat-dissipated, and a second temperature sensor is arranged at the liquid outlet of the internal channel.

### CROSS-REFERENCE TO RELATED APPLICATION

This application claims priority to Chinese Patent Application No. 202210656586.1, titled “LIQUID-COOLED HEAT EXCHANGE SYSTEM AND CONTROL METHOD THEREOF” and filed to the China National Intellectual Property Administration on Jun. 10, 2022, the entire contents of which are incorporated herein by reference.

### TECHNICAL FIELD

The present disclosure relates to the field of liquid cooling of apparatuses, and more particularly, to a liquid-cooled heat exchange system and a control method thereof.

### BACKGROUND

At present, main refrigeration methods of data centers are classified into air cooling and liquid cooling. With increasingly high requirements for energy consumption, the traditional air cooling method has problems of higher energy consumption and lower performance, so it is difficult to meet increasingly high requirements for computing power of the data centers.

Although liquid cooling methods can achieve effects of high density, low noise, low heat transfer temperature difference and year-round natural cooling, the existing liquid cooling methods cannot achieve reasonable regulation and control of temperature of a data room server, and thus cannot meet requirements for heat dissipation of a liquid-cooled server.

### SUMMARY

An objective of the present disclosure is to provide a liquid-cooled heat exchange system and a control method thereof, which can reasonably regulate a temperature of a cooling liquid used for heat exchange of an apparatus within a region to be heat-dissipated, to ensure normal operation of the apparatus within the region to be heat-dissipated.

To achieve the above objective, one aspect of the present disclosure provides a liquid-cooled heat exchange system, which at least includes a heat exchange device, an external circulation loop, an internal circulation loop, an electrically-controlled regulating valve, a pump body, a first temperature sensor, a second temperature sensor, and a controller. The heat exchange device is provided with an external channel and an internal channel, where the external channel is connected in series to the external circulation loop, and the internal channel is connected in series to the internal circulation loop, such that a liquid in the external circulation loop and a liquid in the internal circulation loop exchange heat in the heat exchange device. The internal circulation loop at least includes an internal liquid inlet pipeline, an internal liquid return pipeline and a region to be heat-dissipated, a liquid outlet of the internal channel is communicated with a liquid inlet of the region to be heat-dissipated through the internal liquid inlet pipeline, and a liquid outlet of the region to be heat-dissipated is communicated with a liquid inlet of the internal channel through the internal liquid return pipeline. The electrically-controlled regulating valve is arranged at a liquid inlet of the external channel to control liquid flow of the external channel. The pump body is connected in series to the internal liquid inlet pipeline or the internal liquid return pipeline, the first temperature sensor is arranged at the liquid outlet of the region to be heat-dissipated, and the second temperature sensor is arranged at the liquid outlet of the internal channel. The controller is electrically connected to the electrically-controlled regulating valve, the pump body, the first temperature sensor and the second temperature sensor, respectively.

To achieve the above objective, another aspect of the present disclosure also provides a control method for a liquid-cooled heat exchange system, where the liquid-cooled heat exchange system at least includes a heat exchange device, an external circulation loop, an internal circulation loop, an electrically-controlled regulating valve, a pump body, a first temperature sensor, and a second temperature sensor. The heat exchange device is provided with an external channel and an internal channel, where the external channel is connected in series to the external circulation loop, and the internal channel is connected in series to the internal circulation loop. The internal circulation loop at least includes an internal liquid inlet pipeline, an internal liquid return pipeline and a region to be heat-dissipated, a liquid outlet of the internal channel is communicated with a liquid inlet of the region to be heat-dissipated through the internal liquid inlet pipeline, and a liquid outlet of the region to be heat-dissipated is communicated with a liquid inlet of the internal channel through the internal liquid return pipeline. The electrically-controlled regulating valve is arranged at a liquid inlet of the external channel, the pump body is connected in series to the internal liquid inlet pipeline or the internal liquid return pipeline, the first temperature sensor is arranged at the liquid outlet of the region to be heat-dissipated, and the second temperature sensor is arranged at the liquid outlet of the internal channel. The method includes:
receiving a first detection temperature collected by the first temperature sensor;
calculating a first refrigeration demand based on the first detection temperature and a first preset temperature through a PID algorithm, and regulating a flow of the pump body based on the first refrigeration demand;
receiving a second detection temperature collected by the second temperature sensor; and
calculating a second refrigeration demand based on the second detection temperature and a second preset temperature through the PID algorithm, and regulating a flow of the electrically-controlled regulating valve based on the second refrigeration demand.

As can be seen, according to the technical solutions provided by the present disclosure, the external circulation loop may be employed to exchange heat with the internal circulation loop by means of the heat exchange device, such that the region to be heat-dissipated in the internal circulation loop may be continuously refrigerated. Moreover, the first temperature sensor is arranged at the liquid outlet of the region to be heat-dissipated, and the second temperature sensor is arranged at the liquid outlet of the internal channel. The flow of the pump body is regulated based on the temperature detected by the first temperature sensor, such that corresponding heat dissipation and refrigeration can be carried out to the region to be heat-dissipated according to actual heat dissipation demands of the region to be heat-dissipated. Furthermore, the flow of the electrically-controlled regulating valve is regulated based on the temperature detected by the second temperature sensor, such that refrigeration supply of the external circulation loop can be correspondingly regulated according to heat exchange demands of the internal circulation loop. That is, reasonable regulation of a temperature of a cooling liquid used for heat exchange of an apparatus within the region to be heat-dissipated may be achieved, to ensure normal operation of the apparatus within the region to be heat-dissipated.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a liquid-cooled heat exchange system according to an embodiment provided by the present disclosure;

FIG. 2 is an enlarged view of Part A of FIG. 1;

FIG. 3 is a schematic structural diagram of an external circulation loop of the liquid-cooled heat exchange system according to an embodiment provided by the present disclosure;

FIG. 4 is a schematic structural diagram of an internal circulation loop of the liquid-cooled heat exchange system according to an embodiment provided by the present disclosure; and

FIG. 5 is a step diagram of a control method for a liquid-cooled heat exchange system according to an embodiment provided by the present disclosure.

Reference numerals in the drawings: heat exchange device 1; external channel 11; internal channel 12; external circulation loop 2; external liquid inlet pipeline 21; external liquid return pipeline 22; heat dissipation device 23; automatic exhaust valve 24; internal circulation loop 3; internal liquid inlet pipeline 31; internal liquid return pipeline 32; region to be heat-dissipated 33; liquid charging/discharging port 34; liquid charging/discharging globe valve 341; quick connect coupling 342; filter 35; conductivity meter 36; ball valve 37; pressure sensor 38; electrically-controlled regulating valve 4; pump body 5; first temperature sensor 6; second temperature sensor 7; flowmeter 8; and on-off valve 9.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

At present, main refrigeration methods of data centers are classified into air cooling and liquid cooling. With increasingly high requirements for energy consumption, the traditional air cooling method has problems of higher energy consumption and lower performance, so it is difficult to meet increasingly high requirements for computing power of the data centers.

Although liquid cooling methods can achieve effects of high density, low noise, low heat transfer temperature difference and year-round natural cooling, the existing liquid cooling methods cannot achieve reasonable regulation and control of temperature of a data room server, and thus cannot meet requirements for heat dissipation of a liquid-cooled server. Furthermore, it is unable to achieve cooling and filtering treatment of a cooling liquid transferred into a container of the liquid-cooled server, and thus it is unable to meet the requirements for heat dissipation of the liquid-cooled server and to ensure normal operation of the server for a long time.

Therefore, a liquid-cooled heat exchange system and a control method thereof are urgently needed, which can reasonably regulate a temperature of the cooling liquid used for heat exchange of an apparatus within a region to be heat-dissipated to ensure the normal operation of the apparatus within the region to be heat-dissipated.

The technical solutions in the embodiment of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

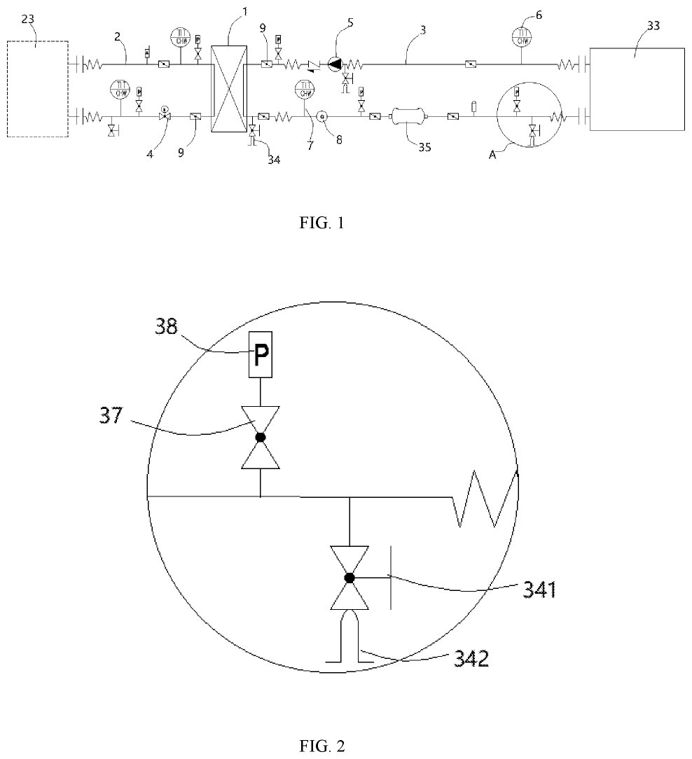

In an implementable embodiment, as shown in FIGS. 1 to 4, a liquid-cooled heat exchange system may at least include a heat exchange device 1, an external circulation loop 2, an internal circulation loop 3, an electrically-controlled regulating valve 4, a pump body 5, a first temperature sensor 6, a second temperature sensor 7, and a controller. The heat exchange device 1 has an external channel 11 and an internal channel 12, where the external channel 11 is connected in series to the external circulation loop 2, and the internal channel 12 is connected in series to the internal circulation loop 3, such that that a liquid in the external circulation loop 2 and a liquid in the internal circulation loop 3 can exchange heat in the heat exchange device 1. Moreover, the liquid in the external channel 11 and the liquid in the internal channel 12 do not blend with each other, such that quality of the cooling liquid in the internal circulation loop 2 is not adversely affected, and different cooling liquids may be used in the external circulation loop 2 and the internal circulation loop 3, thereby reducing use costs.

The internal circulation loop 3 may at least include an internal liquid inlet pipeline 31, an internal liquid return pipeline 32, and a region to be heat-dissipated 33. A liquid outlet of the internal channel 12 is communicated with a liquid inlet of the region to be heat-dissipated 33 through the internal liquid inlet pipeline 31, and a liquid outlet of the region to be heat-dissipated 33 may be communicated with a liquid inlet of the internal channel 12 through the internal liquid return pipeline 32, such that one circulation loop may be formed, and the liquid in the internal circulation loop 3 absorbs heat and heats up within the region to be heat-dissipated 33, and then flows into the internal channel of the heat exchange device 1 for heat exchange and cooling.

The liquid-cooled heat exchange system can reasonably regulate a temperature of a cooling liquid used for heat exchange of an apparatus within the region to be heat-dissipated 33, to ensure normal operation of the apparatus within the region to be heat-dissipated 33. The electrically-controlled regulating valve 4 may be arranged at a liquid inlet of the external channel 11 to control liquid flow of the external channel 11. The pump body 5 is connected in series to the internal liquid inlet pipeline 31 or the internal liquid return pipeline 32, the first temperature sensor 6 is arranged at the liquid outlet of the region to be heat-dissipated 33, and the second temperature sensor 7 is arranged at the liquid outlet of the internal channel 12. The controller (not shown) is electrically connected to the electrically-controlled regulating valve 4, the pump body 5, the first temperature sensor 6 and the second temperature sensor 7, respectively. The controller is configured to receive a temperature detected by the first temperature sensor 6 and a temperature detected by the second temperature sensor 7, and to control the start and stop of the electrically-controlled regulating valve 4 and the pump body 5 and flows thereof. Thus, in actual use, the controller can receive the temperature detected by the first temperature sensor 6 to regulate the flow of the pump body 5, such that corresponding heat dissipation and refrigeration may be performed on the region to be heat-dissipated 33 according to actual heat dissipation demands of the region to be heat-dissipated 33. For example, when the temperature detected by the first temperature sensor 6 is higher than a preset temperature, this indicates that operation of the existing cooling liquid cannot meet the refrigeration demands of the region to be heat-dissipated 33. In this case, it is required to regulate the flow of the pump body 5 based on a differential between the temperature detected by the first temperature sensor 6 and the preset temperature, to control the pump body 5 to accelerate a flow rate of the liquid in the internal circulation loop 3 to meet the demands of the region to be heat-dissipated 33.

Furthermore, the flow of the electrically-controlled regulating valve 4 is regulated based on the temperature detected by the second temperature sensor 7, such that refrigeration supply of the external circulation loop 2 can be correspondingly regulated according to heat exchange demands of the internal circulation loop 3. That is, reasonable regulation of the temperature of the cooling liquid used for heat exchange of an apparatus within the region to be heat-dissipated may be achieved, to ensure normal operation of the apparatus within the region to be heat-dissipated.

In practical application, the liquid-cooled heat exchange system may be applied to cooling of server apparatuses in data centers or offices, and of course, may also be applied to cooling of other apparatuses requiring for heat dissipation. The region to be heat-dissipated 33 may be a server container where a server is placed. The heat exchange device 1 may employ a plate heat exchanger, and of course other heat exchangers may also be employed, which is not specifically limited. The controller may employ a programmable apparatus such as a single chip microcomputer to calculate the differential between the detected temperature and the preset temperature (an expected temperature) by running a PID control algorithm, to control the flow of the electrically-controlled regulating valve 4 and the flow of the pump body 5. Specifically, the flow may be regulated by regulating a valve opening size of the electrically-controlled regulating valve 4. The flow of the pump body 5 may be regulated by regulating a rotating speed of the pump body 5.

It should be pointed out that reference may be made to the prior art for specific structures of the electrically-controlled regulating valve 4, the pump body 5, the first temperature sensor 6 and the second temperature sensor 7, which is not to be described in detail here.

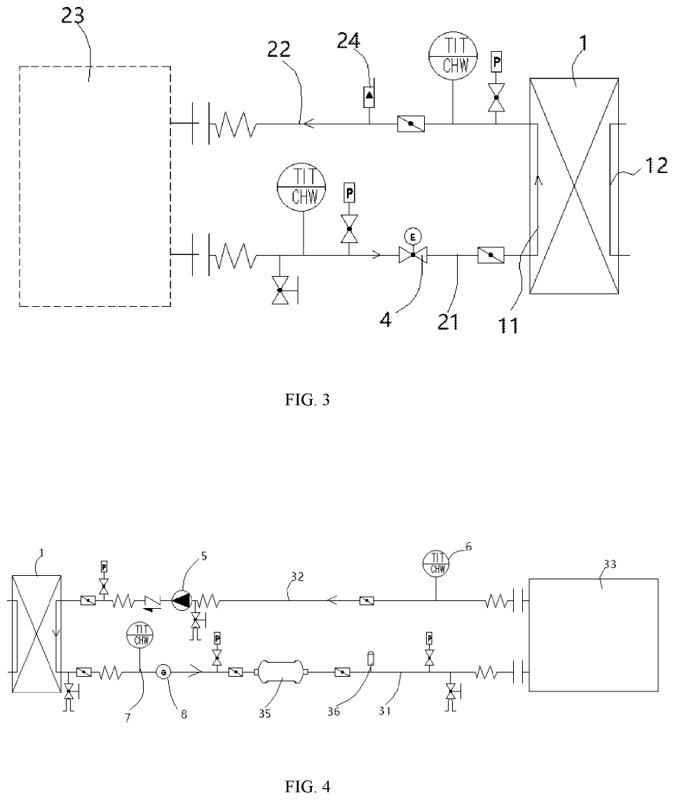

In an implementable embodiment, as shown in FIG. 3, the external circulation loop 2 may at least include an external liquid inlet pipeline 21, an external liquid return pipeline 22, and a heat dissipation device 23. The liquid inlet of the external channel 11 is communicated with a liquid outlet of the heat dissipation device 23 through the external liquid inlet pipeline 21. The liquid outlet of the external channel 11 is communicated with a liquid inlet of the heat dissipation device 23 through the external liquid return pipeline 22.

In practical application, the heat dissipation device 23 may employ a cooling tower or other refrigeration apparatuses, and may be provided with a circulating pump configured to drive circulation flow of an external circulating liquid. The liquid in the external circulation loop 2 is heated up by means of heat exchange between the liquid in the external channel 11 and the liquid in the internal channel 12, the heated liquid flows to the heat dissipation device 23 for cooling treatment, and then the cooled liquid flows back to the external channel 11. In this way, the circulation proceeds in turn.

Further, after the cooling liquid in the internal circulation loop 3 runs for a long time, shortage of the cooling liquid may be caused by volatilization or the like. To facilitate replenishment of the cooling liquid, the internal liquid inlet pipeline 31 and/or the internal liquid return pipeline 32 are provided with a first branch, and the first branch is connected to a liquid charging/discharging port 34, such that the cooling liquid in the internal circulation loop 3 is replenished through the liquid charging/discharging port 34.

Specifically, the liquid charging/discharging port 34 may include a liquid charging/discharging globe valve 341 and a quick connect coupling 342, where one end of the liquid charging/discharging globe valve 341 is communicated with the first branch, and other end of the liquid charging/discharging globe valve 341 is communicated with the quick connect coupling 342. Thus, when it is required to replenish the liquid, an external liquid replenishment apparatus port may be connected to the quick connect coupling 342, and then the liquid charging/discharging globe valve 341 is opened for liquid replenishment. After the liquid replenishment is completed, the liquid charging/discharging globe valve 341 is first closed, and then the external liquid replenishment apparatus port is removed from the quick connect coupling 342.

In practical application, two ends of the liquid charging/discharging globe valve 341 may be female adapters, where one end of the liquid charging/discharging globe valve 341 is connected to a port of the first branch, and the other end of the liquid charging/discharging globe valve 341 is in threaded connection with the quick connect coupling 342.

In an implementable embodiment, the liquid-cooled heat exchange system may also include a filter 35. The filter 35 is connected in series to the internal liquid inlet pipeline 31 to filter the liquid entering the region to be heat-dissipated 33 from the internal liquid inlet pipeline 31, to ensure cleanliness of the cooling liquid in the internal circulation loop 3.

The external circulation loop 2 and the internal circulation loop 3 are respectively connected in series with a flowmeter 8, which is configured to detect the flow of the liquid in the external circulation loop 2 and the flow of the liquid in the internal circulation loop 3, to determine whether an actual flow is consistent with a preset flow, and thus to determine whether the whole loop runs properly.

Further, the liquid-cooled heat exchange system further includes a conductivity meter 36, where the conductivity meter 36 is connected in series with the internal liquid inlet pipeline 31, and the conductivity meter 36 is positioned between the filter and the liquid inlet of the region to be heat-dissipated 33 to measure conductivity of the liquid entering the region to be heat-dissipated 33 from the internal liquid inlet pipeline 31. When the measured conductivity value is higher than a preset value, an alarm may be triggered and handled by an operator to ensure the normal operation of the server within the region to be heat-dissipated 33.

An automatic exhaust valve 24 is connected in series with the external circulation loop 2, and the automatic exhaust valve 24 is configured to discharge a gas from a pipeline of the external circulation loop 2.

Further, the external circulation loop 2 and the internal circulation loop 3 are connected in series with a plurality of on-off valves 9, respectively. The plurality of on-off valves 9 are sequentially arranged at intervals along corresponding pipelines (pipelines connected to the plurality of on-off valves 9), such that there is no need to discharge all the liquid in subsequent maintenance, and only the on-off valves 9 at two ends of a corresponding maintenance point need to be closed, making the maintenance more convenient.

The internal liquid inlet pipeline 31 and/or the internal liquid return pipeline 32 are provided with a second branch, which is connected to a pressure sensor 38 through a ball valve 37, where the ball valve 37 is normally open. When the pressure sensor 38 needs maintenance, the corresponding ball valve 37 may be closed to facilitate the maintenance.

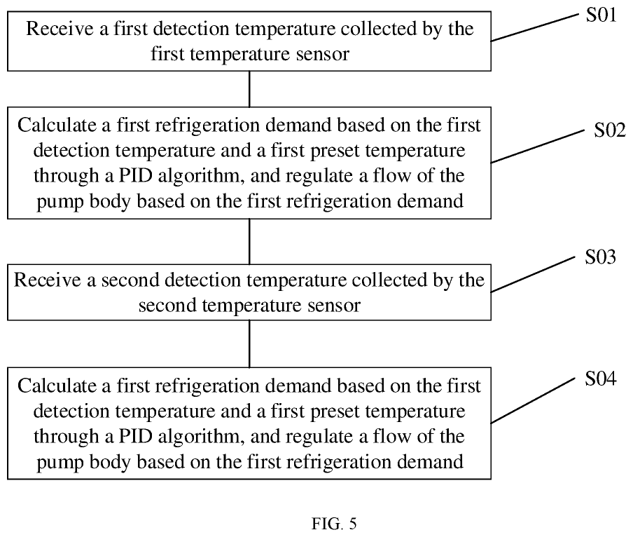

Based on the same inventive concept, referring to FIG. 5, the present disclosure also provides a control method for a liquid-cooled heat exchange system. The liquid-cooled heat exchange system at least includes a heat exchange device 1, an external circulation loop 2, an internal circulation loop 3, an electrically-controlled regulating valve 4, a pump body 5, a first temperature sensor 6, and a second temperature sensor 7. The heat exchange device 1 is provided with an external channel 11 and an internal channel 12, where the external channel 11 is connected in series to the external circulation loop 2, and the internal channel 12 is connected in series to the internal circulation loop 3. The internal circulation loop 3 at least includes an internal liquid inlet pipeline 31, an internal liquid return pipeline 32 and a region to be heat-dissipated 33, where a liquid outlet of the internal channel 12 is communicated with a liquid inlet of the region to be heat-dissipated 33 through the internal liquid inlet pipeline 31, and a liquid outlet of the region to be heat-dissipated 33 is communicated with a liquid inlet of the internal channel 12 through the internal liquid return pipeline 32. The electrically-controlled regulating valve 4 is arranged at a liquid inlet of the external channel 11, the pump body 5 is connected in series to the internal liquid inlet pipeline 31 or the internal liquid return pipeline 32, the first temperature sensor 6 is arranged at the liquid outlet of the region to be heat-dissipated 33, and the second temperature sensor 7 is arranged at the liquid outlet of the internal channel 12. The method includes following steps.

In Step S01, a first detection temperature collected by the first temperature sensor 6 is received.

In Step S02, a first refrigeration demand is calculated based on the first detection temperature and a first preset temperature through a PID algorithm, and a flow of the pump body 5 is regulated based on the first refrigeration demand.

The controller receives, in real time, a temperature of the liquid outlet of the region to be heat-dissipated 33, which is detected by the first temperature sensor 6, where the temperature of the liquid outlet of the region to be heat-dissipated 33 may represent heat dissipation of the apparatus within the region to be heat-dissipated 33 by the cooling liquid in the internal circulation loop 3.

When the controller determines that there exists a differential between the temperature detected by the first temperature sensor 6 and a first preset temperature in the system, the controller may calculate rotating speed regulation amount of the pump body 5 based on the PID algorithm to regulate the rotating speed of the pump body 5, thereby regulating the flow of the pump body 5.

In Step S03, a second detection temperature collected by the second temperature sensor 7 is received.

In Step S04: a second refrigeration demand is calculated based on the second detection temperature and a second preset temperature through the PID algorithm, and a flow rate of the electrically-controlled regulating valve 4 is regulated based on the second refrigeration demand.

Meanwhile, the controller also receives a temperature of the liquid outlet of the internal channel 12, which is detected by the second temperature sensor 7, where the temperature of the liquid outlet of the internal channel 12 may represent heat exchange between the cooling liquid in the external circulation loop 2 and the cooling liquid in the internal circulation loop 3.

When the controller determines that there exists a differential between the temperature detected by the second temperature sensor 7 and a second preset temperature in the system, the controller may calculate opening regulation amount of the electrically-controlled regulating valve 4 based on PID algorithm to regulate the opening of the electrically-controlled regulating valve 4, thereby controlling the flow of the electrically-controlled regulating valve 4. In this way, based on temperature monitoring and regulation of the flows of the external circulation loop 2 and the internal circulation loop 3, the temperature of the cooling liquid used for heat exchange of the apparatus within the region to be heat-dissipated and the temperature of heat exchange between the external circulation loop 2 and the internal circulation loop 3 can be reasonably regulated to ensure the normal operation of the apparatus within the region to be heat-dissipated.

As can be seen, according to the technical solutions provided by the present disclosure, the external circulation loop may be employed to exchange heat with the internal circulation loop by means of the heat exchange device, such that the region to be heat-dissipated in the internal circulation loop may be continuously refrigerated. Moreover, the first temperature sensor is arranged at the liquid outlet of the region to be heat-dissipated, and the second temperature sensor is arranged at the liquid outlet of the internal channel. The flow of the pump body is regulated based on the temperature detected by the first temperature sensor, such that corresponding heat dissipation and refrigeration can be carried out to the region to be heat-dissipated according to actual heat dissipation demands of the region to be heat-dissipated. Furthermore, the flow of the electrically-controlled regulating valve is regulated based on the temperature detected by the second temperature sensor, such that refrigeration supply of the external circulation loop can be correspondingly regulated according to heat exchange demands of the internal circulation loop. That is, reasonable regulation of a temperature of a cooling liquid used for heat exchange of an apparatus within the region to be heat-dissipated may be achieved, to ensure normal operation of the apparatus within the region to be heat-dissipated.

Further, the internal liquid inlet pipeline and/or the internal liquid return pipeline are provided with a first branch, and the first branch is connected to a liquid charging/discharging port, such that the cooling liquid may be conveniently replenished in case of shortage of the cooling liquid.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A liquid-cooled heat exchange system, at least comprising a heat exchange device (1), an external circulation loop (2), an internal circulation loop (3), an electrically-controlled regulating valve (4), a pump body (5), a first temperature sensor (6), a second temperature sensor (7), and a controller; wherein
the heat exchange device (1) is provided with an external channel (11) and an internal channel (12), the external channel (11) is connected in series to the external circulation loop (2), and the internal channel (12) is connected in series to the internal circulation loop (3);
the internal circulation loop (3) at least comprises an internal liquid inlet pipeline (31), an internal liquid return pipeline (32) and a region to be heat-dissipated (33), a liquid outlet of the internal channel (12) is communicated with a liquid inlet of the region to be heat-dissipated (33) through the internal liquid inlet pipeline (31), and a liquid outlet of the region to be heat-dissipated (33) is communicated with a liquid inlet of the internal channel (12) through the internal liquid return pipeline (32);
the electrically-controlled regulating valve (4) is arranged at a liquid inlet of the external channel (11) to control liquid flow of the external channel (11);
the pump body (5) is connected in series to the internal liquid inlet pipeline (31) or the internal liquid return pipeline (32), the first temperature sensor (6) is arranged at the liquid outlet of the region to be heat-dissipated (33), and the second temperature sensor (7) is arranged at the liquid outlet of the internal channel (12); and
the controller is electrically connected to the electrically-controlled regulating valve (4), the pump body (5), the first temperature sensor (6) and the second temperature sensor (7), respectively.

2. The liquid-cooled heat exchange system according to claim 1, wherein the external circulation loop (2) at least comprises an external liquid inlet pipeline (21), an external liquid return pipeline (22), and a heat dissipation device (23);
the liquid inlet of the external channel (11) is communicated with a liquid outlet of the heat dissipation device (23) through the external liquid inlet pipeline (21); and
a liquid outlet of the external channel (11) is communicated with a liquid inlet of the heat dissipation device (23) through the external liquid return pipeline (22).

3. The liquid-cooled heat exchange system according to claim 2, wherein the internal liquid inlet pipeline (31) and/or the internal liquid return pipeline (32) are provided with a first branch, and the first branch is connected to a liquid charging/discharging port (34); and
the liquid charging/discharging port (34) comprises a liquid charging/discharging globe valve (341) and a quick connect coupling (342), one end of the liquid charging/discharging globe valve (341) is communicated with the first branch, and other end of the liquid charging/discharging globe valve (341) is communicated with the quick connect coupling (342).

4. The liquid-cooled heat exchange system according to claim 3, wherein the liquid-cooled heat exchange system further comprises a filter (35); and
the filter (35) is connected in series with the internal liquid inlet pipeline (31) to filter a liquid entering the region to be heat-dissipated (33) from the internal liquid inlet pipeline (31).

5. The liquid-cooled heat exchange system according to claim 4, wherein the external circulation loop (2) and the internal circulation loop (3) are connected in series with a flowmeter (8), respectively.

6. The liquid-cooled heat exchange system according to claim 5, wherein the liquid-cooled heat exchange system further comprises a conductivity meter (36); and
the conductivity meter (36) is connected in series with the internal liquid inlet pipeline (31), and the conductivity meter (36) is positioned between the filter (35) and the liquid inlet of the region to be heat-dissipated (33) to measure conductivity of the liquid entering the region to be heat-dissipated (33) from the internal liquid inlet pipeline (31).

7. The liquid-cooled heat exchange system according to claim 6, wherein an automatic exhaust valve (24) is connected in series with the external circulation loop (2), and the automatic exhaust valve (24) is configured to discharge a gas from a pipeline of the external circulation loop (2).

8. The liquid-cooled heat exchange system according to claim 7, wherein the external circulation loop (2) and the internal circulation loop (3) are connected in series with a plurality of on-off valves (9), respectively; and
the plurality of on-off valves (9) are sequentially arranged at intervals along corresponding pipelines.

9. The liquid-cooled heat exchange system according to claim 8, wherein the internal liquid inlet pipeline (31) and/or the internal liquid return pipeline (32) are provided with a second branch, and the second branch is connected to a pressure sensor (38) through a ball valve (37).

10. A control method for a liquid-cooled heat exchange system, the liquid-cooled heat exchange system at least comprising a heat exchange device (1), an external circulation loop (2), an internal circulation loop (3), an electrically-controlled regulating valve (4), a pump body (5), a first temperature sensor (6), and a second temperature sensor (7); wherein the heat exchange device (1) is provided with an external channel (11) and an internal channel (12), the external channel (11) is connected in series to the external circulation loop (2), and the internal channel (12) is connected in series to the internal circulation loop (3); the internal circulation loop (3) at least comprises an internal liquid inlet pipeline (31), an internal liquid return pipeline (32) and a region to be heat-dissipated (33), a liquid outlet of the internal channel (12) is communicated with a liquid inlet of the region to be heat-dissipated (33) through the internal liquid inlet pipeline (31), and a liquid outlet of the region to be heat-dissipated (33) is communicated with a liquid inlet of the internal channel (12) through the internal liquid return pipeline (32); the electrically-controlled regulating valve (4) is arranged at a liquid inlet of the external channel (11), the pump body (5) is connected in series to the internal liquid inlet pipeline (31) or the internal liquid return pipeline (32), the first temperature sensor (6) is arranged at the liquid outlet of the region to be heat-dissipated (33), and the second temperature sensor (7) is arranged at the liquid outlet of the internal channel (12); and the method comprises:
receiving a first detection temperature collected by the first temperature sensor (6);
calculating a first refrigeration demand based on the first detection temperature and a first preset temperature through a PID algorithm, and regulating a flow of the pump body (5) based on the first refrigeration demand;
receiving a second detection temperature collected by the second temperature sensor (7); and
calculating a second refrigeration demand based on the second detection temperature and a second preset temperature through the PID algorithm, and regulating a flow of the electrically-controlled regulating valve (4) based on the second refrigeration demand.
